(19) United States
(12) Patent Application Publication
(10) Pub. No.: US 2021/0147975 A1
(43) Pub. Date: May 20, 2021

(54) EVAPORATION SOURCE FOR DEPOSITION OF EVAPORATED MATERIAL ON A SUBSTRATE, DEPOSITION APPARATUS, METHOD FOR MEASURING A VAPOR PRESSURE OF EVAPORATED MATERIAL, AND METHOD FOR DETERMINING AN EVAPORATION RATE OF AN EVAPORATED MATERIAL

(71) Applicant: Applied Materials, Inc., Santa Clara, CA (US)

(72) Inventors: Thomas GEBELE, Freigericht (DE); Wolfgang BUSCHBECK, Hanau (DE)

(21) Appl. No.: 17/046,975

(22) PCT Filed: Apr. 18, 2018
(86) PCT No.: PCT/EP2018/059893

§ 371 Date: Oct. 12, 2020

(51) Int. Cl. C23C 14/54; C23C 14/24; C23C 14/56

(52) U.S. Cl. CPC C23C 14/543; C23C 14/56; C23C 14/243; C23C 14/544

(57) ABSTRACT

An evaporation source for deposition of evaporated material on a substrate is described. The evaporation source including a crucible for material evaporation; a distribution assembly with one or more outlets for providing the evaporated material to the substrate, the distribution assembly being in fluid communication with the crucible; and a measurement assembly. The measurement assembly includes a tube connecting an interior space of the distribution assembly with a pressure sensor.

### TECHNICAL FIELD

Embodiments of the present disclosure relate to evaporation sources for deposition of evaporated material on a substrate. In particular, embodiments of the present disclosure relate to evaporation sources having a measurement device for determining an evaporation rate of evaporated material, particularly evaporated organic material. Further, embodiments of the present disclosure relate to methods of measuring a vapor pressure of evaporated material in an evaporation source as well as to methods of determining an evaporation rate of evaporated material. Moreover, embodiments of the present disclosure relate to deposition apparatuses, particularly vacuum deposition apparatuses for the production of organic light-emitting diodes (OLEDs).

### BACKGROUND

Organic evaporators are a tool for the production of organic light-emitting diodes (OLED). OLEDs are a special type of light-emitting diode in which the emissive layer comprises a thin-film of certain organic compounds. Organic light emitting diodes (OLEDs) are used in the manufacture of television screens, computer monitors, mobile phones, other hand-held devices, etc., for displaying information. OLEDs can also be used for general space illumination. The range of colors, brightness, and viewing angle possible with OLED displays is greater than that of traditional LCD displays, because OLED pixels directly emit light and do not involve a back light. Therefore, the energy consumption of OLED displays is considerably less than that of traditional LCD displays. Further, the fact that OLEDs can be manufactured onto flexible substrates results in further applications.

The functionality of an OLED depends on the coating thickness of the organic material. This thickness has to be within a predetermined range. In the production of OLEDs, the deposition rate at which the coating with organic material is effected is controlled to lie within a predetermined tolerance range. In other words, the deposition rate of an organic evaporator has to be controlled thoroughly in the production process.

Accordingly, for OLED applications, but also for other evaporation processes, a high accuracy of the evaporation rate over a comparably long time is needed. There is a plurality of measurement systems available for measuring the evaporation rate of evaporators. However, these measurement systems show some deficiencies with respect to handling, reliability, maintenance, accuracy, sufficient stability over the operating time, and cost efficiency.

Accordingly, there is a continuing demand for evaporation sources and deposition apparatus having improved measurement systems for measuring the evaporation rate as well as for improved methods for measuring the evaporation rate which overcome at least some problems of the state of the art.

### SUMMARY

In light of the above, an evaporation source for deposition of evaporated material on a substrate, a deposition apparatus for applying material to a substrate, a method of measuring a vapor pressure in an evaporation source, and a method for determining an evaporation rate of an evaporated material in an evaporation source according to the independent claims are provided. Further aspects, advantages, and features are apparent from the dependent claims, the description, and the accompanying drawings.

According to an aspect of the present disclosure, an evaporation source for deposition of evaporated material on a substrate is provided. The evaporation source includes a crucible for material evaporation and a distribution assembly with one or more outlets for providing the evaporated material to the substrate. The distribution assembly is in fluid communication with the crucible. Further, the evaporation source includes a measurement assembly including a tube connecting an interior space of the distribution assembly with a pressure sensor.

According to a further aspect of the present disclosure, an evaporation source for deposition of a plurality of evaporated materials on a substrate is provided. The evaporation source includes a first crucible for evaporation of a first material and a first distribution assembly with one or more outlets for providing the first evaporated material to the substrate. The first distribution assembly is in fluid communication with the first crucible. Additionally, the evaporation source includes a second crucible for evaporation of a second material and a second distribution assembly with one or more outlets for providing the second evaporated material to the substrate. The second distribution assembly is in fluid communication with the second crucible. Further, the evaporation source includes a measurement assembly including a tube arrangement and a purge gas introduction arrangement. The tube arrangement has a first tube and a second tube. The first tube connects a first interior space of the first distribution assembly with a pressure sensor. The second tube connects a second interior space of the second distribution assembly with the pressure sensor. Further, the purge gas introduction arrangement has a first purge gas introduction device connected to the first tube as well as a second purge gas introduction device connected to the second tube.

According to a further aspect of the present disclosure, an evaporation source for deposition of evaporated material on a substrate is provided. The evaporation source includes a crucible for material evaporation and a distribution assembly with one or more outlets for providing the evaporated material to the substrate. The distribution assembly is in fluid communication with the crucible. Further, the evaporation source includes a measurement assembly including a measurement assembly comprising a tube connecting an interior space of the crucible with a pressure sensor.

According to another aspect of the present disclosure, a deposition apparatus for applying material to a substrate is provided. The deposition apparatus includes a vacuum chamber and an evaporation source provided in the vacuum chamber. The evaporation source includes a crucible and a distribution assembly. Further, the deposition apparatus includes a measurement assembly for measuring a vapor pressure in the distribution assembly. The measurement assembly includes a tube having a first end and a second end. The first end of the tube is arranged in an interior space of the distribution assembly. The second end of the tube is connected to a pressure sensor.

According to a further aspect of the present disclosure, a method of measuring a vapor pressure in an evaporation source is provided. The evaporation source has a crucible and a distribution assembly. The method of measuring the vapor pressure in the evaporation source includes providing a measurement assembly. The measurement assembly includes a tube having a first end and a second end. Additionally, the method includes arranging the first end in an interior space of the distribution assembly and connecting the second end to a pressure sensor. Further, the method includes evaporating a material for providing the evaporated material, guiding the evaporated material from the crucible into the distribution assembly, and measuring a pressure provided at the second end of the tube using the pressure sensor.

According to yet another aspect of the present disclosure, a method for determining an evaporation rate of an evaporated material in an evaporation source is provided. The method for determining the evaporation rate includes measuring a vapor pressure of the evaporated material in the evaporation source. Further, the method includes calculating the evaporation rate from the measured vapor pressure.

According to a further aspect of the present disclosure, a method of measuring a vapor pressure difference in an evaporation source is provided. The evaporation source has a crucible and a distribution assembly. The method includes providing a first measurement assembly including a tube connecting an interior space of the distribution assembly with a first pressure sensor. The tube has a tube opening provided at a first position in the interior space of the distribution assembly. Additionally, the method includes providing a second measurement assembly including a further tube connecting an interior space of the evaporation source with a second pressure sensor. The further tube has a further tube opening provided at a second position in the interior space of the distribution assembly. Alternatively, the further tube opening is provided at a second position in an interior space of the crucible. Further, the method includes measuring the vapor pressure difference in the evaporation source using the first pressure sensor and the second pressure sensor.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic view of an evaporation source according to embodiments described herein;

FIGS. 2 to 5 and 6A to 6D show schematic views of evaporation sources according to further embodiments described herein;

FIG. 7 shows a cross-sectional top view of an evaporation source according to further embodiments described herein;

FIGS. 8A and 8B show schematic views of a deposition apparatus according to embodiments described herein;

FIG. 9 shows a schematic view of a deposition apparatus according to further embodiments described herein;

FIGS. 10A and 10B show flowcharts for illustrating a method of measuring a vapor pressure in an evaporation source according to embodiments described herein;

FIG. 11 shows a flowchart for illustrating a method for determining an evaporation rate of an evaporated material in an evaporation source according to embodiments described herein; and

FIG. 12 shows a flowchart for illustrating a method of measuring a vapor pressure difference in an evaporation source according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

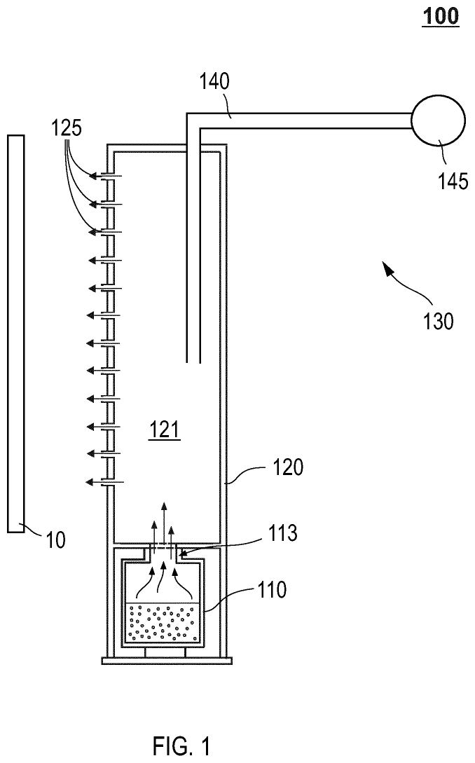

With exemplary reference to FIG. 1, an evaporation source 100 for deposition of evaporated material on a substrate according to the present disclosure is described. According to embodiments which can be combined with any other embodiments described herein, the evaporation source 100 includes a crucible 110 for material evaporation and a distribution assembly 120. For instance, the distribution assembly 120 can be a distribution tube or distribution pipe. The distribution assembly 120 includes one or more outlets 125 for providing the evaporated material to a substrate 10, as exemplarily shown in FIG. 1. For instance, the one or more outlets may be nozzles. Further, the distribution assembly 120 is in fluid communication with the crucible. For example, the distribution assembly may be connected to the crucible via a connection duct 113, as exemplarily shown in FIG. 1. Additionally, the evaporation source 100 includes a measurement assembly 130 comprising a tube 140 connecting an interior space 121 of the distribution assembly 120 to a pressure sensor 145. Accordingly, beneficially the pressure sensor can be used to measure the vapor pressure of the evaporated material in the interior space of the measurement assembly. Since the evaporation rate is a direct function of the vapor pressure in the distribution assembly, the measurement assembly 130 can be used to determine the evaporation rate. Accordingly, embodiments described herein beneficially provide for conducting in situ vapor pressure measurements and for determining the evaporation rate in situ.

Accordingly, embodiments of the evaporation source as described herein are improved compared to conventional evaporation sources, particularly with respect to the measurement system for determining the evaporation rate. More specifically, by providing a measurement assembly configured for determining the evaporation rate from a measured vapor pressure, one or more deficiencies of conventional evaporation rate measurement systems, particularly quartz crystal microbalances (QCMs), can be overcome. For example, quartz crystal microbalances used for evaporation rate measurements can have some deficiencies with respect to handling, reliability, maintenance, accuracy, sufficient stability over the operating time, and cost efficiency. For measuring a deposition rate, QCMs include an oscillation crystal for measuring a mass variation of deposited material on the oscillation crystal per unit area by measuring the change in frequency of an oscillation crystal resonator. In order to optimize the measurement accuracy, the QCMs need to be cooled, e.g. by gas cooling using nitrogen. Accordingly, deposition rate measurement systems using QCMs typically need a significant amount of nitrogen. Further, the deposited material on the oscillation crystal needs to be removed, e.g. by heating, on a regular basis. Moreover, QCMs can be difficult to integrate and limited in continuous operating/measurement, resulting in increased costs. The problems associated with the determination of evaporation rates using QCMs are at least partially or even completely overcome by the measurement assembly of the evaporation source as described herein.

Before various further embodiments of the present disclosure are described in more detail, some aspects with respect to some terms used herein are explained.

In the present disclosure, an “evaporation source for deposition of evaporated material on a substrate” can be understood as a device or assembly configured for providing evaporated material to be deposited on a substrate. Accordingly, typically an “evaporation source” is configured for deposition of evaporated material on a substrate. In particular, the evaporation source can be configured for deposition of organic materials, e.g. for OLED display manufacturing, on large area substrates.

For instance, a “large area substrate” can have a main surface with an area of 0.5 m² or larger, particularly of 1 m² or larger. In some embodiments, a large area substrate can be GEN 4.5, which corresponds to about 0.67 m² of substrate (0.73×0.92 m), GEN 5, which corresponds to about 1.4 m² of substrate (1.1 m×1.3 m), GEN 7.5, which corresponds to about 4.29 m² of substrate (1.95 m×2.2 m), GEN 8.5, which corresponds to about 5.7 m² of substrate (2.2 m×2.5 m), or even GEN 10, which corresponds to about 8.7 m² of substrate (2.85 m×3.05 m). Even larger generations such as GEN 11 and GEN 12 and corresponding substrate areas can similarly be implemented.

In the present disclosure, the term “substrate” may particularly embrace substantially inflexible substrates, e.g., a wafer, slices of transparent crystal such as sapphire or the like, or a glass plate. However, the present disclosure is not limited thereto, and the term “substrate” may also embrace flexible substrates such as a web or a foil. The term “substantially inflexible” is understood to distinguish over “flexible”. Specifically, a substantially inflexible substrate can have a certain degree of flexibility, e.g. a glass plate having a thickness of 0.5 mm or below, wherein the flexibility of the substantially inflexible substrate is small in comparison to the flexible substrates. According to embodiments described herein, the substrate may be made of any material suitable for material deposition. For instance, the substrate may be made of a material selected from the group consisting of glass (for instance soda-lime glass, borosilicate glass etc.), metal, polymer, ceramic, compound materials, carbon fiber materials or any other material or combination of materials which can be coated by a deposition process.

In the present disclosure, a “crucible for material evaporation” can be understood as a crucible configured for evaporating a material provided in the crucible. A “crucible” can be understood as a device having a reservoir for the material to be evaporated by heating the crucible. Accordingly, a “crucible” can be understood as a source material reservoir which can be heated to vaporize the source material into a gas by at least one of evaporation and sublimation of the source material. Typically, the crucible includes a heater to vaporize the source material in the crucible into a gaseous source material. For instance, initially the material to be evaporated can be in the form of a powder. The reservoir can have an inner volume for receiving the source material to be evaporated, e.g. an organic material. For example, the volume of the crucible can be between 100 cm³ and 3000 cm³, particularly between 700 cm³ and 1700 cm³, more particularly 1200 cm³. In particular, the crucible may include a heating unit configured for heating the source material provided in the inner volume of the crucible up to a temperature at which the source material evaporates. For instance, the crucible may be a crucible for evaporating organic materials, e.g. organic materials having an evaporation temperature of about 100° C. to about 600° C. Accordingly, in the present disclosure, the term “evaporated material” may refer to an evaporated organic material, particularity suitable for OLED production.

In the present disclosure, a “distribution assembly” can be understood as an assembly configured for providing evaporated material, particularly a plume of evaporated material, from the distribution assembly to the substrate. For example, the distribution assembly may include a distribution pipe which can be an elongated cube. For instance, a distribution pipe as described herein may provide a line source with a plurality of openings and/or nozzles which are arranged in at least one line along the length of the distribution pipe. For example, the distribution assembly, particularly the distribution pipe, can be made of titanium.

Accordingly, the distribution assembly can be a linear distribution showerhead, for example, having a plurality of openings (or an elongated slit) disposed therein. Further, typically the distribution assembly can have an enclosure, hollow space, or pipe, in which the evaporated material can be provided or guided, for example from the evaporation crucible to the substrate. According to embodiments which can be combined with any other embodiments described herein, the length of the distribution pipe may correspond at least to the height of the substrate to be deposited. In particular, the length of the distribution pipe may be longer than the height of the substrate to be deposited, at least by 10% or even 20%. For example, the length of the distribution pipe can be 1.3 m or above, for example 2.5 m or above. Accordingly, a uniform deposition at the upper end of the substrate and/or the lower end of the substrate can be provided. According to an alternative configuration, the distribution assembly may include one or more point sources which can be arranged along a vertical axis.

Accordingly, a “distribution assembly” as described herein may be configured to provide a line source extending essentially vertically. In the present disclosure, the term “essentially vertically” is understood particularly when referring to the substrate orientation, to allow for a deviation from the vertical direction of 10° or below. This deviation can be provided because a substrate support with some deviation from the vertical orientation might result in a more stable substrate position. Yet, the substrate orientation during deposition of the organic material is considered essentially vertical, which is considered different from the horizontal substrate orientation. Accordingly, the surface of the substrates can be coated by a line source extending in one direction corresponding to one substrate dimension and a translational movement along the other direction corresponding to the other substrate dimension.

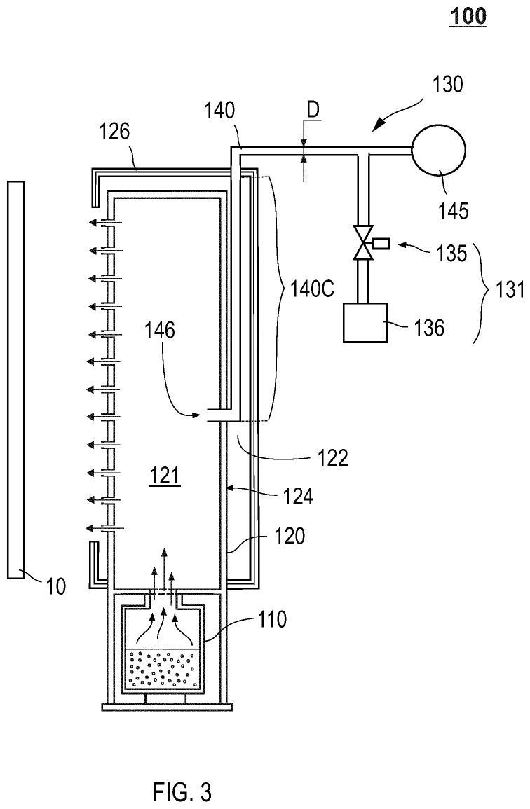

In the present disclosure, a “measurement assembly” can be understood as an assembly having a measurement device for conducting a measurement, particularly a pressure measurement. More specifically, typically the measurement assembly includes a pressure sensor which is connected with an interior space of the distribution assembly, e.g. via a tube 140 as shown in FIG. 1. For example, the tube 140 can have a diameter D of 1.0 mm≤D≤7.5 mm, particularly D=5 mm±1 mm. Typically, the diameter D of the tube of the measurement assembly is constant over the length of the tube. The length L of the tube can be of L 0.5 m≤L≤2.0 m, e.g L=1.0 m±0.1 m. The diameter D of the tube 140 of the measurement assembly 130 is exemplarily indicated in FIG. 3.

A “pressure sensor” can be understood as a device configured for measuring a pressure. For instance, the pressure sensor can be a pressure sensor selected from the group consisting: a mechanical pressure sensor, a capacitive pressure sensor, particularly a capacitive diaphragm gauge (CDG), and a thermal conductivity/convection vacuum gauge (pirani type). According to an example the pressure sensor can be a high precision diaphragm gauge. A high precision diaphragm gauge beneficially provides for measurements with high accuracy, high resolution, high stability and repeatability, particularly at full scale.

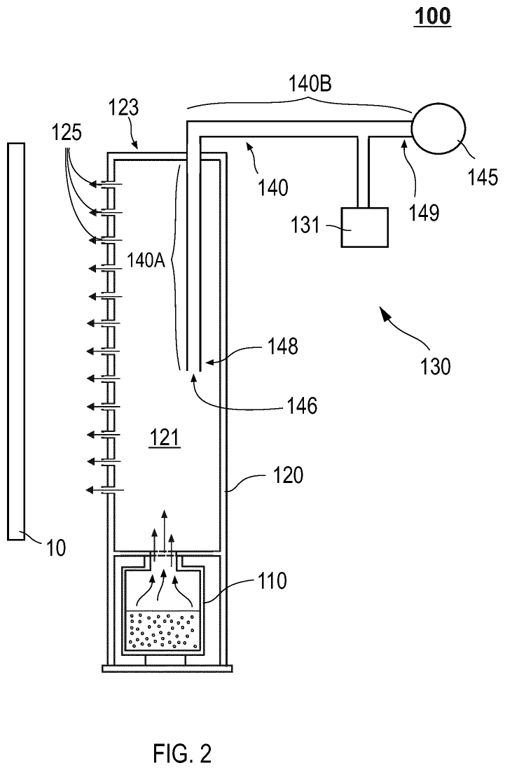

As exemplarily shown in FIG. 2, according to some embodiments which can be combined with other embodiments described herein, the tube 140 includes a first portion 140A arranged in the interior space 121 of the distribution assembly 120. Additionally, the tube 140 includes a second portion 140B arranged outside the distribution assembly 120. Accordingly, the tube 140 connecting the interior space 121 of the distribution assembly 120 to the pressure sensor 145 can be heated at the side of the distribution assembly and can be maintained at room temperature at the side of the pressure sensor 145.

Typically, the first portion 140A of the tube includes a tube opening 146, as exemplarily shown in FIG. 2. More specifically, the tube opening 146 can be provided at a first end 148 of the tube 140. Further, with exemplary reference to FIG. 2, the tube 140 can be arranged to enter the distribution assembly 120 through a top wall 123 of the distribution assembly 120. Alternatively, the tube 140 can be arranged to enter the distribution assembly 120 through a side wall 124 of the distribution assembly 120, as exemplarily shown in FIG. 3.

With exemplary reference to FIG. 2, according to some embodiments which can be combined with other embodiments described herein, the measurement assembly 130 further includes a purge gas introduction device 131 connected to the tube 140. In particular, the purge gas introduction device 131 can be connected to the tube 140 outside the distribution assembly 120. For instance, the purge gas introduction device 131 can be connected to the second portion 140B of the tube, as exemplarily shown in FIG. 3. More specifically, the purge gas introduction device 131 can be connected to the tube close to a second end 149 of the tube 140. In other words, the purge gas introduction device 131 can be connected to the tube in front of the pressure sensor 145.

In the present disclosure, a “purge gas introduction device” can be understood as a device configured for providing a purge gas. In particular, the purge gas introduction device can be configured for providing a purge gas flow Q′ of 0.1 sccm≤Q′≤1.0 sccm, e.g. Q′=0.5 sccm±0.05 sccm. In particular, according to embodiments which can be combined with any other embodiments described herein, the purge gas introduction device 131 can include a mass flow controller 135, as exemplarily shown in FIG. 3. Typically, the mass flow controller 135 is connected to a purge gas source, particularly an inert gas source 136. For instance, the inert gas source 136 can be an argon gas source. Accordingly, the mass flow controller can be configured for controlling the purge gas flow Q′. In other words, the mass flow controller can be used to provide a constant purge gas flow Q′ of a selected purge gas flow.

Accordingly, providing a purge gas introduction device as described herein has the advantage that a small known purge gas mass flow, e.g. an inert gas such as argon, can be introduced into the tube 140 of the measurement assembly, such that the pressure sensor can be protected from condensation and/or contamination of evaporated material. Further, it is to be understood that the purge gas may act as a transfer medium between the evaporated material provided in the distribution assembly and the pressure sensor.

It is to be understood that the purge gas introduced into the tube of the measurement assembly may shift the pressure in the distribution assembly of the evaporation source synchronal to a higher pressure level measured by the pressure sensor. In this regard, it is to be noted that the constant purge gas flow Q′ provided by the purge gas introduction device 131 is relatively low, e.g. 0.1 sccm≤Q′≤1.0 sccm, such that the effect of the additional pressure resulting from the purge gas is negligible, particularly in a typical case wherein a pressure inside the distribution assembly of the evaporation source is of approximately 1 Pa (0.01 mbar).

Further, according to some embodiments which can be combined with any other embodiment described herein, the purge gas introduction device 131, particularly the mass flow controller 135, is configured to reduce or stop the purge gas flow in a periodical manner. Accordingly, the purge gas flow in the tube 140 of the measurement assembly 130 can be minimized, which can be beneficial for achieving the optimal measurement resolution. In other words, providing a purge gas introduction device capable of periodically switching between high purge gas flow associated with high pressure sensor protection and medium measurement resolution and low purge gas flow associated with lower sensor protection and high measurement resolution can be beneficial for optimizing the operation of the measurement assembly with respect to accuracy, reliability, stability over the operating time, and cost efficiency.

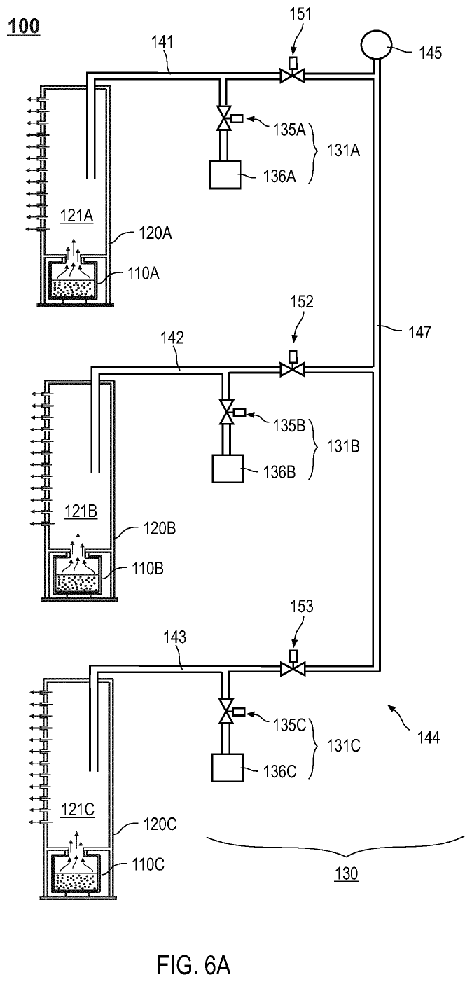

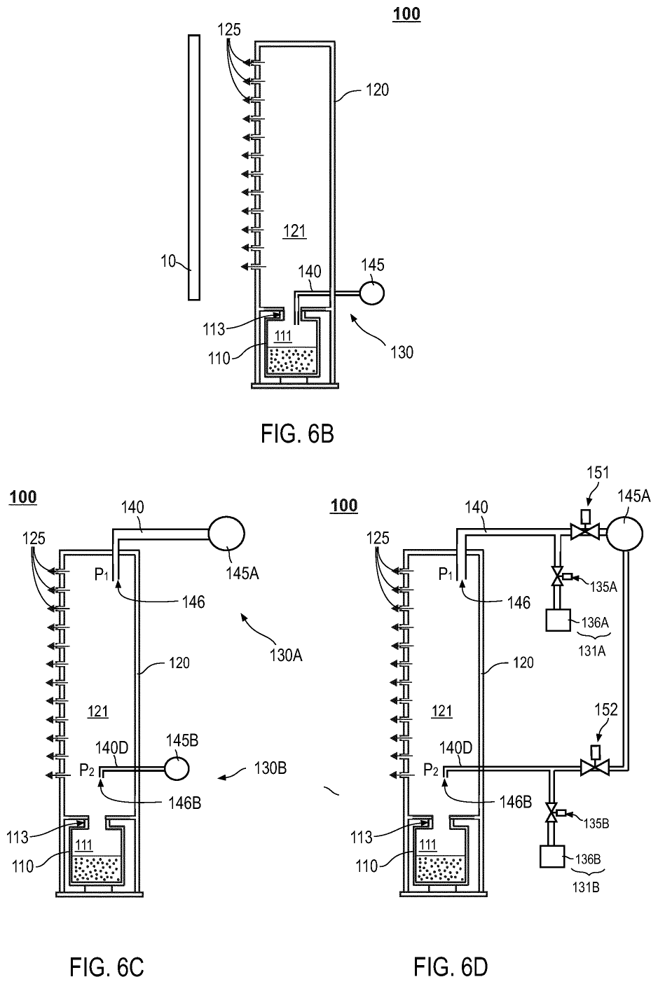

Further, it is to be understood that stopping the purge gas flow or reducing the purge gas flow from a high level to a lower level typically results in a pump down curve which could also be used to analyze and extrapolate the real vapor pressure in the distribution assembly. In particular, it is to be noted that the inner volume of the tube of the measurement assembly is relatively small (e.g. about 20 cm³ in the case of a tube with a diameter of D=5 mm and a length L of L=1000 mm) which beneficially results in a pump down time of e.g. 10 s (<20 s). Accordingly, the time to go from a first pressure A to a second pressure B could also be used as a pressure indicator. Providing the tube 140, as exemplarily described with reference to FIGS. 1 to 5, or the tube arrangement 144, as exemplarily described with reference to FIG. 6A, with a small volume beneficially allows for fast pressure sensor cycling, e.g. between the pressure measurements in the first distribution assembly 120A, the second distribution assembly 120B and the third distribution assembly 120C, as exemplarily shown in FIG. 6A.

With exemplary reference to FIG. 3, according to some embodiments which can be combined with other embodiments described herein, the tube 140 can be partially arranged in a space 122 between the distribution assembly 120 and a heater 126 of the distribution assembly 120. More specifically, as exemplarily shown in FIG. 3, a third portion 140C of the tube 140 may be arranged in the space 122 between the distribution assembly 120 and the heater 126 of the distribution assembly 120. Typically, the third portion 140C of the tube 140 is provided between the first portion 140A and the second portion 140B. Typically, the heater 126 is provided for heating the distribution assembly, particularly the walls of the distribution assembly. For instance, as exemplarily shown in FIG. 3, the heater can be provided at a distance with respect to the outside surfaces of the walls of the distribution assembly. Accordingly, the distribution assembly can be heated to a temperature such that the evaporated material provided by the evaporation crucible does not condense at an inner portion of the wall of the distribution assembly.

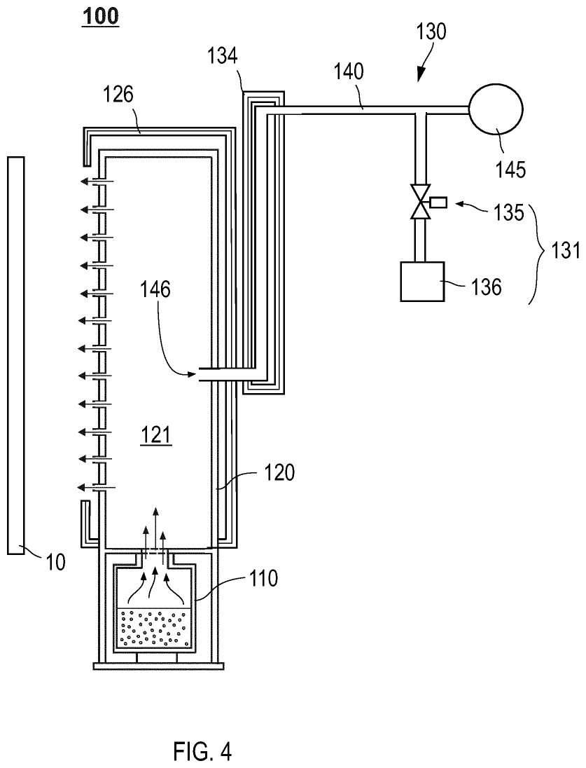

As exemplarily shown in FIG. 4, according to some embodiments which can be combined with other embodiments described herein, the measurement assembly 130 can further include a heating arrangement 134. In particular, the heating arrangement 134 can be at least partially arranged around the tube 140. Typically, the heating arrangement 134 is configured to heat the tube to the evaporation temperature of the employed source material. Accordingly, beneficially condensation of evaporated material inside the tube 140 of the measurement assembly can be avoided.

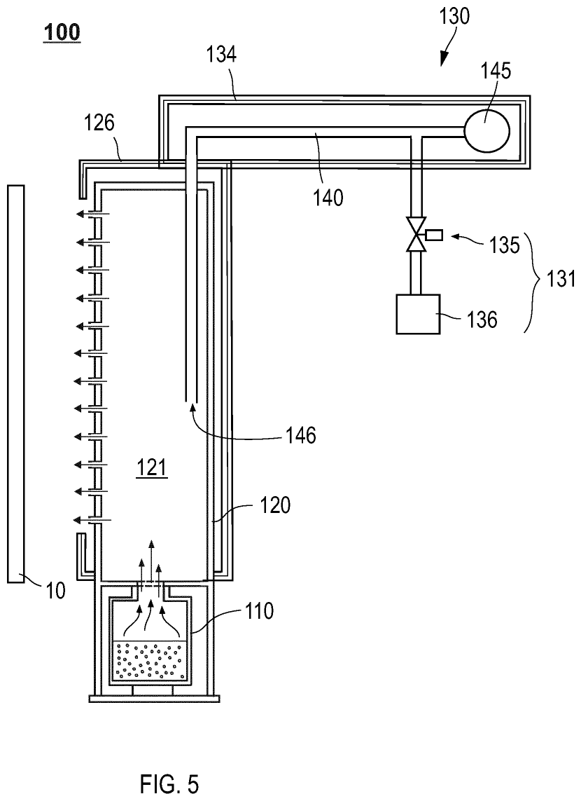

With exemplary reference to FIG. 5, according to some embodiments which can be combined with other embodiments described herein, the heating arrangement 134 may be provided around the pressure sensor 145. In particular, the heating arrangement 134 can be arranged to heat the entire tube 140 arranged outside the distribution assembly as well as the pressure sensor 145. Optionally, a purge gas introduction device 131 as shown in FIG. 5 can be provided.

With exemplary reference to FIG. 6A, an evaporation source 100 for deposition of a plurality of evaporated materials on a substrate according to the present disclosure is described. An evaporation source for deposition of a plurality of evaporated materials on a substrate can be understood as an evaporation source configured for depositing two or more different evaporated materials on a substrate.

As exemplarily shown in FIG. 6A, according to embodiments which can be combined with other embodiments described herein, the evaporation source 100 for deposition of a plurality of evaporated materials on a substrate includes a first crucible 110A for evaporation of a first material and a first distribution assembly 120A. The first distribution assembly 120A includes one or more outlets for providing the first evaporated material to the substrate. The first distribution assembly 120A is in fluid communication with the first crucible 110A.

Additionally, the evaporation source 100 includes a second crucible 110B for evaporation of a second material and a second distribution assembly 120B. The second distribution assembly 120B includes one or more outlets for providing the second evaporated material to the substrate. The second distribution assembly 120B is in fluid communication with the second crucible 110B.

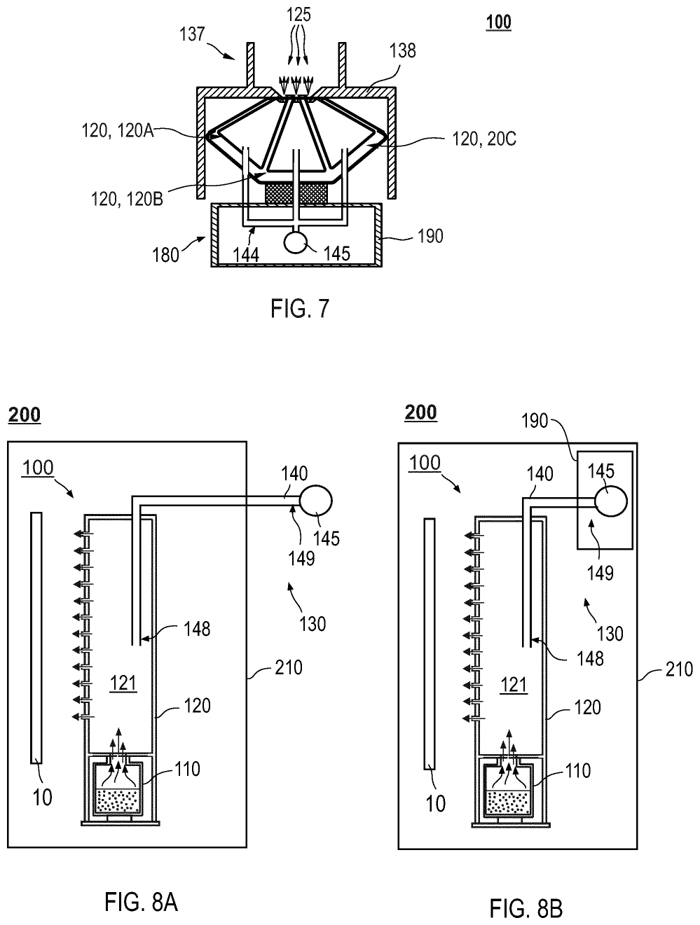

Further, as exemplarily shown in FIG. 6A, the evaporation source 100 for deposition of a plurality of evaporated materials on a substrate can include a third crucible 110C for evaporation of a third material and a third distribution assembly 120CA. The third distribution assembly 120C includes one or more outlets for providing the third evaporated material to the substrate. The third distribution assembly 120C is in fluid communication with the third crucible 110C. An evaporation source having three distribution assemblies may also be referred to as triple evaporation source, also described with reference to FIG. 7 in more detail.

It is to be understood that the features of the embodiments as described with reference to FIGS. 1 to 5 can, mutatis mutandis, be applied to the evaporation source for deposition of a plurality of evaporated materials as exemplarily shown in FIG. 6A.

Additionally, as exemplarily shown in FIG. 6A, the evaporation source 100 for deposition of a plurality of evaporated materials on a substrate includes a measurement assembly 130 including a tube arrangement 144 and a purge gas introduction arrangement. The tube arrangement 144 includes a first tube 141 and a second tube 142. Additionally, the tube arrangement 144 may include a third tube 143. The first tube 141 connects a first interior space 121A of the first distribution assembly 120A with a pressure sensor 145. The second tube 142 connects a second interior space 121B of the second distribution assembly 120B with the pressure sensor 145. Additionally, the third tube 143 typically connects a third interior space 121C of the third distribution assembly 120C with the pressure sensor 145. As exemplarily shown in FIG. 6A, a connection tube 147 may connect the first tube 141, the second tube 142 and the third tube 143 to the pressure sensor 145. Accordingly, beneficially the pressure sensor 145 may be connected to multiple distribution assemblies, e.g., distribution assemblies as exemplarily shown in FIG. 6A.

Further, as exemplarily shown in FIG. 6A, the purge gas introduction arrangement may include a first purge gas introduction device 131A connected to the first tube 141. Additionally, the purge gas introduction arrangement may include a second purge gas introduction device 131B connected to the second tube 142. Further, the purge gas introduction arrangement may include a third purge gas introduction device 131C connected to the third tube 143.

It is to be understood that features as described with respect to the purge gas introduction device 131, e.g. with reference to FIGS. 1 to 5, can, mutatis mutandis, be applied to the first purge gas introduction device 131A, the second purge gas introduction device 131B, and the third purge gas introduction device 131C. Accordingly, the first purge gas introduction device 131A can include a first mass flow controller 135A, the second purge gas introduction device 131B can include a second mass flow controller 135B, and the third purge gas introduction device 131C can include a third mass flow controller 135C. The first mass flow controller 135A can be connected to a first purge gas source, particularly a first inert gas source 136A. The second mass flow controller 135B can be connected to a second purge gas source, particularly a second inert gas source 136B. The third mass flow controller 135C can be connected to a third purge gas source, particularly a third inert gas source 136C. Although not explicitly shown, it is to be understood that alternatively, the first mass flow controller 135A, the second mass flow controller 135B, and the third mass flow controller 135C may be connected to a common purge gas source.

With exemplary reference to FIG. 6A, according to some embodiments a first valve 151 may be provided in the first tube 141, particularly between the first purge gas introduction device 131A and the connection tube 147. Additionally or alternatively, a second valve 152 may be provided in the second tube 142, particularly between the second purge gas introduction device 131B and the connection tube 147. Further, additionally or alternatively, a third valve 153 may be provided in the third tube 143, particularly between the third purge gas introduction device 131C and the connection tube 147.

Providing valves (e.g. a first valve 151, a second valve 152, and a third valve 153) has the advantage that the pressure in the individual distribution assemblies can be measured separately. For instance, the pressure in the individual distribution assemblies can be measured subsequently, i.e. in a cycling measurement sequence.

Further, providing separate purge gas introductions devices (e.g. a first purge gas introductions device 131A, a second purge gas introductions device 131B, and a third purge gas introductions device 131C) has the advantage that purge gas flow in the respective tube (i.e. in the first tube 141, in the second tube 142, and the third tube 143) can be set individually to provide the optimal measurement conditions. For instance, for measuring the pressure inside a selected distribution assembly of a plurality of distribution assemblies, the purge gas flow in the tube connecting the selected distribution assembly with the pressure sensor can be set to be lower than the purge gas flow in the other tubes. Accordingly, beneficially contamination and/or condensation in the other tubes can be avoided. Consequently, beneficially one single pressure sensor can be connected to individual distribution assemblies in a cyclic or periodic manner, e.g. using low purge flow at the connected distribution assembly to be measured, while for the other non-connected distribution assemblies, a higher, more protecting purge gas flow can be used.

FIG. 7 shows a cross-sectional top view of an evaporation source according to further embodiments which can be combined with other embodiments described herein. In particular, FIG. 7 shows an example of an evaporation source having three distribution assemblies, e.g. three distribution pipes, also referred to as triple evaporation source. Accordingly, a triple evaporation source can be understood as an evaporation source having a first distribution assembly 120A, a second distribution assembly 120B, and a third distribution assembly 120C. In particular, the three distribution assemblies and the corresponding crucibles of the triple evaporation source can be provided next to each other. Accordingly, beneficially the triple evaporation source can provide an evaporation source array, e.g. wherein more than one kind of material, for instance three different materials, can be evaporated at the same time.

With exemplary reference to FIG. 7, according to some embodiments which can be combined with any other embodiments described herein, the distribution assembly 120 can be configured as a distribution pipe having a noncircular cross-section perpendicular to the length of the distribution pipe. For example, the cross-section perpendicular to the length of the distribution pipe can be triangular with rounded corners and/or cut-off corners as a triangle. In particular, FIG. 7 shows a first distribution assembly 120A configured as a first distribution pipe, a second distribution assembly 120B configured as a second distribution pipe, and a third distribution assembly 120C configured as a third distribution pipe. The first distribution pipe, the second distribution pipe, and the third distribution pipe have a substantially triangular cross-section perpendicular to the length of the distribution pipes. According to embodiments which can be combined with any other embodiment described herein, each distribution assembly is in fluid communication with the respective crucible, as exemplarily described with reference to FIG. 6A.

As exemplarily shown in FIG. 7, according to some embodiments which can be combined with any other embodiment described herein, an evaporator control housing 180 may be provided adjacent to a distribution assembly 120 as described herein. Typically, the evaporator control housing is configured to provide and maintain atmospheric pressure inside the evaporator control housing. Accordingly, as exemplarily shown in FIG. 7, the evaporator control housing can be configured to house a pressure sensor 145 as described herein. Further, the evaporator control housing may be configured for housing one or more other components or devices selected from the group consisting of: a switch, a valve, a controller, a cooling unit, a cooling control unit, a heating control unit, a power supply, and a measurement device.

Although not explicitly shown in FIG. 7, it is to be understood that in the exemplary embodiment shown in FIG. 7, purge gas introduction devices and valves can be provided, e.g. a first purge gas introduction device 131A, a second purge gas introduction device 131B, a third purge gas introduction device 131C, a first valve 151, a second valve 152 and a third valve 153, as described with reference to FIG. 6A.

According to some embodiments which can be combined with any other embodiment described herein, the distribution assembly, particularly the distribution pipe, may be heated by heating elements which are provided inside the distribution assembly. The heating elements can be electrical heaters which can be provided by heating wires, e.g. coated heating wires, which are clamped or otherwise fixed to the inner tubes. Further, with exemplary reference to FIG. 7, a cooling shield 138 can be provided. The cooling shield 138 may include sidewalls which are arranged such that a U-shaped cooling shield is provided in order to reduce the heat radiation towards the deposition area, i.e. a substrate and/or a mask. For example, the cooling shield can be provided as metal plates having conduits for cooling fluid, such as water, attached thereto or provided therein. Additionally, or alternatively, thermoelectric cooling devices or other cooling devices can be provided to cool the cooled shields. Typically, the outer shields, i.e. the outermost shields surrounding the inner hollow space of a distribution pipe, can be cooled.

In FIG. 7, for illustrative purposes, evaporated source material exiting the outlets of the distribution assemblies are indicated by arrows. Due to the essentially triangular shape of the distribution assemblies, the evaporation cones originating from the three distribution assemblies are in close proximity to each other. Accordingly, beneficially mixing of the source material from the different distribution assemblies can be improved. In particular, the shape of the cross-section of the distribution pipes allow to place the outlets or nozzles of neighboring distribution pipes close to each other. According to some embodiments, which can be combined with other embodiments described herein, a first outlet or nozzle of the first distribution assemblies and a second outlet or nozzle of the second distribution assemblies can have a distance of 50 mm or below, e.g. 30 mm or below, or 25 mm or below, such as from 5 mm to 25 mm. More specifically, the distance of the first outlet or nozzle to a second outlet or nozzle can be 10 mm or below.

As further shown in FIG. 7, a shielding device, particularly a shaper shielding device 137, can be provided, for example, attached to the cooling shield 138 or as a part of the cooling shield. By providing shaper shields, the direction of the vapor exiting the distribution pipe or pipes through the outlets can be controlled, i.e. the angle of the vapor emission can be reduced. According to some embodiments, at least a portion of evaporated material provided through the outlets or nozzles is blocked by the shaper shield. Accordingly, beneficially the width of the emission angle can be controlled.

With exemplary reference to FIG. 6B, an evaporation source 100 for deposition of evaporated material on a substrate according to another embodiment is described. According to embodiments which can be combined with any other embodiments described herein, the evaporation source 100 includes a crucible 110 for material evaporation and a distribution assembly 120 with one or more outlets 125 for providing the evaporated material to the substrate. The distribution assembly is in fluid communication with the crucible. Further, the evaporation source 100 includes a measurement assembly 130 including a tube 140 connecting an interior space 111 of the crucible 110 with a pressure sensor 145. In particular, the tube 140 typically has a tube opening 146 provided in the interior space 111 of the crucible 110. More specifically, the tube opening 146 may be arranged at an upper portion of the interior space 111 of the crucible 110.

It is to be understood that the features as described with the exemplary embodiments shown in FIGS. 1 to 6A, mutatis mutandis, may be applied to the embodiment shown in FIG. 6B.

Accordingly, the exemplarily embodiment as shown in FIG. 6B represents an alternative configuration of an evaporation source having a measurement system for conducting in situ vapor pressure measurements and for determining the evaporation rate.

With exemplary reference to FIG. 6C, an evaporation source 100 for deposition of evaporated material on a substrate according to a further embodiment is described. According to embodiments which can be combined with any other embodiments described herein, the evaporation source 100 includes a crucible 110 for material evaporation and a distribution assembly 120 with one or more outlets 125 for providing the evaporated material to the substrate. The distribution assembly is in fluid communication with the crucible. Further, the evaporation source 100 includes a first measurement assembly 130A and a second measurement assembly 130B. The first measurement assembly 130A includes a tube 140 connecting an interior space 121 of the distribution assembly 120 with a first pressure sensor 145A. The tube 140 has a tube opening 146 provided at a first position P1 in the interior space 121 of the distribution assembly 120. In particular, the first position P1 of the tube opening 146 can be at an upper portion of the distribution assembly, as exemplarily shown in FIG. 6C. The second measurement assembly 130B includes a further tube 140D connecting an interior space of the evaporation source with a second pressure sensor 145B. The further tube 140D has a further tube opening 146B provided at a second position P2 in the interior space 121 of the distribution assembly. For instance, the second position P2 of the further tube opening 146B can be at a lower portion of the distribution assembly, as exemplarily shown in FIG. 6C. Alternatively, the further tube opening 146B can be provided at a second position P2 in an interior space 111 of the crucible 110, as exemplarily described with reference to FIG. 6B.

Accordingly, the exemplary embodiment as shown in FIG. 6C, beneficially provides for the capability of measuring a vapor pressure difference in the evaporation source, particularity between a first position P1 and a second position P2 in the interior space of the evaporation source. Typically, the first position P1 is a position at an upper portion of the evaporation source, particularly an upper portion of the interior space of the distribution assembly. The second position P2 is typically a position at a lower portion of the evaporation source, e.g. a position at a lower portion of the interior space 121 of the distribution assembly 120 or a position at an upper portion of the interior space 111 of the crucible 110.

Accordingly, the embodiment as exemplarily shown in FIG. 6C is beneficially configured for conducting a method of measuring a vapor pressure difference in the evaporation source. For instance, measuring the vapor pressure difference in the distribution assembly, e.g. with respect to the nozzle diameters (total nozzle conductance), can in particular be beneficial for optimizing evaporation conditions, particularly in the case of very low evaporating/coating rates.

It is to be understood that the features as described with the exemplary embodiments shown in FIGS. 1 to 6B, mutatis mutandis, may be applied to the embodiment shown in FIG. 6C. In particular, it is to be understood that instead of using a second pressure sensor, the further tube 140D can be connected to the first pressure sensor 145A and a purge gas introduction device as described herein can be connected to the tube 140 and the further tube 140D. For example a first purge gas introduction device 131A and/or a second purge gas introduction device 131B can be provided as exemplarily shown in FIG. 6D. Further, a first valve 151 can be provided in the tube and/or second valve 152 can be provided in the further tube 140D.

With exemplary reference to the flowchart shown in FIG. 12, a method 500 of measuring a vapor pressure difference in an evaporation source 100 having a crucible 110 and a distribution assembly 120 is described. The method includes providing (represented by block 510 in FIG. 12) a first measurement assembly 130A including a tube 140 connecting an interior space 121 of the distribution assembly 120 with a first pressure sensor 145A. The tube 140 has a tube opening 146 provided at a first position P1 in the interior space 121 of the distribution assembly 120, as exemplarily shown in FIG. 6C. Further, the method includes providing (represented by block 520 in FIG. 12) a second measurement assembly 130B including a further tube 140D connecting an interior space of the evaporation source with a second pressure sensor 145B. The further tube 140D has a further tube opening 146B provided at a second position P2 in the interior space 121 of the distribution assembly 120, as exemplarily shown in FIG. 6C. Alternatively, the further tube opening 146B can be provided at a second position P2 in an interior space 111 of the crucible 110, as exemplarily described with reference to FIG. 6B. Further, the method includes measuring (represented by block 530 in FIG. 12) the vapor pressure difference in the evaporation source using the first pressure sensor 145A and the second pressure sensor 145B. Alternatively, instead of using the first pressure sensor 145A and the second pressure sensor 145B, a single pressure sensor (e.g. the first pressure sensor 145A) may be used for measuring the vapor pressure difference in the evaporation source, particularly in the case of employing an evaporation source having a measurement assembly as exemplarily shown in FIG. 6D.

With exemplary reference to FIGS. 8A and 8B, a deposition apparatus according to embodiments of the present disclosure are described. According to embodiments which can be combined with other embodiments described herein, the deposition apparatus includes a vacuum chamber 210 and an evaporation source 100 provided in the vacuum chamber 210. The evaporation source 100 includes a crucible 110 and a distribution assembly 120. In particular, the evaporation source 100 provided in the vacuum chamber 210 can be an evaporation source 100 according to any embodiments described herein, e.g. an evaporation source as exemplarily described with reference to FIGS. 1 to 7. Further, as exemplarily shown in FIGS. 8A and 8B, a measurement assembly 130 for measuring a vapor pressure in the distribution assembly is provided. The measurement assembly includes a tube 140 having a first end 148 and a second end 149. The first end 148 of the tube 140 is arranged in an interior space 121 of the distribution assembly 120. The second end 149 of the tube 140 is connected to a pressure sensor 145. In particular, the pressure sensor can be provided in an atmospheric space.

For example, the atmospheric space in which the pressure sensor 145 can be provided may be a space provided outside the vacuum chamber 210, as exemplarily shown in FIG. 8A. A configuration with the pressure sensor 145 provided outside the vacuum chamber 210 can in particular be beneficial in the case that the position of the evaporation source is fixed relative to the vacuum chamber, i.e. a configuration in which the substrate is moved relative to the evaporation source during the deposition process. Alternatively, the atmospheric space can be provided by an atmospheric box 190 or atmospheric container provided inside the vacuum chamber 210, as exemplarily shown in FIG. 8B. For example, the atmospheric box 190 can be connected to the distribution assembly 120, as exemplarily shown in FIG. 7, which can be beneficial for configurations in which the evaporation source is moved relative to the substrate during the deposition process. An “atmospheric space” can be understood as a space having atmospheric pressure. Accordingly, an atmospheric box or atmospheric container can be understood as a box or container, i.e. a closed space, configured to maintain atmospheric pressure inside the atmospheric box or atmospheric container. For instance, the atmospheric space may be provided by the evaporator control housing 180, as exemplarily shown in FIG. 7. Accordingly, the evaporator control housing 180 can be used as atmospheric box 190 or atmospheric container.

In the present disclosure, the term “vacuum” can be understood in the sense of a technical vacuum having a vacuum pressure of less than, for example, 10 mbar. Typically, the pressure in a vacuum chamber as described herein may be between 10⁻⁵ mbar and about 10⁻⁸ mbar, more typically between 10⁻⁵ mbar and 10⁻⁷ mbar, and even more typically between about 10⁻⁶ mbar and about 10⁻⁷ mbar. According to some embodiments, the pressure in the vacuum chamber may be considered to be either the partial pressure of the evaporated material within the vacuum chamber or the total pressure (which may approximately be the same when only the evaporated material is present as a component to be deposited in the vacuum chamber). In some embodiments, the total pressure in the vacuum chamber may range from about 10⁻⁴ mbar to about 10⁻⁷ mbar, especially in the case that a second component besides the evaporated material is present in the vacuum chamber (such as a gas or the like). Accordingly, the vacuum chamber can be a “vacuum deposition chamber”, i.e. a vacuum chamber configured for vacuum deposition.

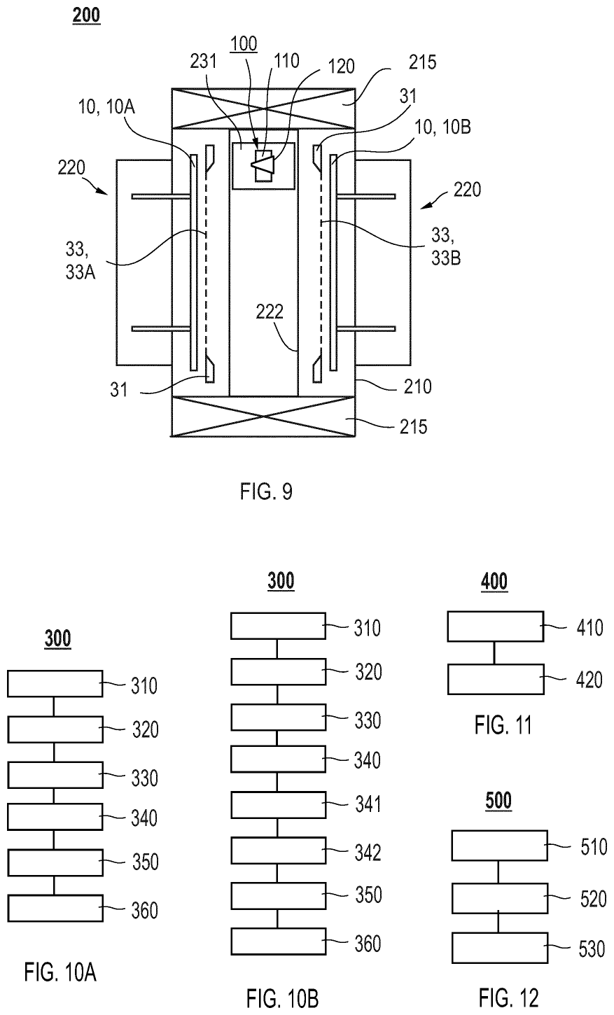

With exemplary reference to FIG. 9, some further optional aspects of a deposition apparatus according to the present disclosure are described. According to some embodiments, which can be combined with other embodiments described herein, the vacuum deposition apparatus includes a vacuum chamber 210, an evaporation source 100 according to any embodiments described herein provided in the vacuum chamber 210, and a substrate support 220 configured for supporting a substrate 10 during material deposition. In particular, the evaporation source 100 can be provided on a track or linear guide 222, as exemplarily shown in FIG. 9. Typically, the linear guide 222 is configured for a translational movement of the evaporation source 100. Further, a drive for providing a translational movement of the evaporation source can be provided. In particular, a transportation apparatus for contactless transportation of the evaporation source may be provided in the vacuum deposition chamber.

Further, as exemplarily shown in FIG. 9, a source support 231 configured for the translational movement of the evaporation source 100 along the linear guide 222 may be provided. Typically, the source support 231 supports the crucible 110 and the distribution assembly 120 provided over the evaporation crucible, as schematically shown in FIG. 9. Accordingly, the vapor generated in the evaporation crucible can move upwardly and out of the one or more outlets of the distribution assembly. Accordingly, as described herein, the distribution assembly is configured for providing evaporated material, particularly a plume of evaporated organic material, from the distribution assembly 120 to the substrate 10.

As exemplarily shown in FIG. 9, the vacuum chamber 210 may have gate valves 215 via which the vacuum deposition chamber can be connected to an adjacent routing module or an adjacent service module. Typically, the routing module is configured to transport the substrate to a further vacuum chamber, e.g. for further processing. The service module is configured for maintenance of the evaporation source. In particular, the gate valves allow for a vacuum seal to an adjacent vacuum chamber, e.g. of the adjacent routing module or the adjacent service module, and can be opened and closed for moving a substrate and/or a mask into or out of the vacuum chamber 210 of the deposition apparatus 200, as exemplarily shown in FIG. 9.

With exemplary reference to FIG. 9, according to embodiments which can be combined with any other embodiment described herein, two substrates, e.g. a first substrate 10A and a second substrate 10B, can be supported on respective transportation tracks within the vacuum chamber 210. Further, two tracks for providing masks 33 thereon can be provided. In particular, the tracks for transportation of a substrate carrier and/or a mask carrier may be provided with a further transportation apparatus for contactless transportation of the carriers.

Typically, coating of the substrates may include masking the substrates by respective masks, e.g. by an edge exclusion mask or by a shadow mask. According to some embodiments, the masks, e.g. a first mask 33A corresponding to a first substrate 10A and a second mask 33B corresponding to a second substrate 10B, are provided in a mask frame 31 to hold the respective mask in a predetermined position, as exemplarily shown in FIG. 9.

As shown in FIG. 9, the linear guide 222 provides a direction of the translational movement of the evaporation source 100. On both sides of the evaporation source 100, a mask 33, e.g. a first mask 33A for masking a first substrate 10A and second mask 33B for masking a second substrate 10B can be provided. The masks can extend essentially parallel to the direction of the translational movement of the evaporation source 100. Further, the substrates at the opposing sides of the evaporation source can also extend essentially parallel to the direction of the translational movement.

It is to be understood that FIG. 9 only shows a schematic representation of the evaporation source 100, and that the evaporation source 100 provided in the vacuum chamber 210 of the deposition apparatus 200 can have any configuration of the embodiments described herein, as exemplarily described with reference to FIGS. 1 to 7, 8A and 8B.

With exemplary reference to the flowcharts shown in FIGS. 10A and 10B, embodiments of a method 300 of measuring a vapor pressure in an evaporation source according to the present disclosure are described. According to embodiments which can be combined with other embodiments described herein, the method 300 includes providing (represented by block 310 in FIG. 10A) a measurement assembly including a tube having a first end and a second end. In particular, the measurement assembly can be a measurement assembly 130 according to embodiments as exemplarily described with reference to FIGS. 1 to 8. Additionally, the method 300 includes arranging (represented by block 320 in FIG. 10A) the first end 148 of the tube 140 in an interior space 121 of the distribution assembly 120, as exemplarily illustrated in FIG. 2. Further, the method 300 includes connecting (represented by block 330 in FIG. 10A) the second end 149 to a pressure sensor 145. For instance, the pressure sensor 145 can be provided in an atmospheric space. For example, the atmospheric space can be a space provided outside a vacuum chamber 210, as exemplarily shown in FIG. 8A. Alternatively, the atmospheric space can be provided by an atmospheric box 190 or atmospheric container provided inside the vacuum chamber 210, as exemplarily shown in FIG. 8B. Additionally, the method 300 includes evaporating (represented by block 340 in FIG. 10A) a material for providing the evaporated material. Further, the method 300 includes guiding (represented by block 350 in FIG. 10A) the evaporated material from the crucible into the distribution assembly. Additionally, the method 300 includes measuring (represented by block 360 in FIG. 10A) a pressure provided at the second end of the tube using the pressure sensor. In particular, the pressure p2 in the distribution assembly can be calculated from the equation p2 [mbar]=p1 [mbar]−(Q [mbar·l·s⁻¹]/L[l·s⁻¹]), wherein p1 is the pressure measured by the pressure sensor, Q is the mass flow, and L is the fluid conductance. The mass flow Q can be controlled by a mass flow controller as described herein. The fluid conductance L of the tube as described herein is constant.

With exemplary reference to the flowchart shown in FIG. 10B, according to some embodiments which can be combined with other embodiments described herein, the method 300 of measuring a vapor pressure in an evaporation source further includes heating (represented by block 341 in FIG. 10B) at least a portion of the tube. In particular, heating at least a portion of the tube typically involves using a heater 126 of the distribution assembly 120, as exemplarily described with reference to FIG. 3. Further, heating at least a portion of the tube can involve using a heating arrangement 134, as exemplarily described with reference to FIGS. 4 and 5.

Further, with exemplary reference to the flowchart shown in FIG. 10B, according to some embodiments which can be combined with other embodiments described herein, the method 300 of measuring a vapor pressure in an evaporation source further includes introducing (represented by block 342 in FIG. 10B) a purge gas into the tube 140. In particular, introducing a purge gas into the tube 140 typically involves introducing the purge gas into an end portion of the tube 140 being connected to the pressure sensor 145.

With exemplary reference to the flowchart shown in FIG. 11, embodiments of a method 400 for determining an evaporation rate of an evaporated material in an evaporation source according to the present disclosure are described. According to embodiments which can be combined with other embodiments described herein, the method 400 includes measuring (represented by block 410 in FIG. 11) a vapor pressure of the evaporated material in the evaporation source. Further, the method 400 includes calculating (represented by block 420 in FIG. 11) the evaporation rate from the measured vapor pressure. The evaporation rate can be calculated from the measured vapor pressure, because the evaporation rate is a direct function of the vapor pressure in the distribution assembly. Accordingly, for the vapor pressure calculation typically a calibration of the measurement assembly is carried out in advance.

In view of the above, it is to be understood that compared to the state of the art, embodiments of the evaporation source, the deposition apparatus, the method of measuring a vapor pressure in the evaporation source, and the method of determining an evaporation rate of an evaporated material in the evaporation source are improved with respect to handling and/or reliability and/or maintenance and/or, accuracy and/or stability over the operating time and/or cost efficiency.

While the foregoing is directed to embodiments, other and further embodiments may be devised without departing from the basic scope, and the scope is determined by the claims that follow.

1. An evaporation source for deposition of evaporated material on a substrate, comprising:
a crucible for material evaporation;
a distribution assembly with one or more outlets for providing the evaporated material to the substrate, the distribution assembly being in fluid communication with the crucible; and
a measurement assembly comprising a tube connecting an interior space of the distribution assembly with a pressure sensor.

2. The evaporation source of claim 1, the measurement assembly further comprising a purge gas introduction device connected to the tube.

3. The evaporation source of claim 1, the tube having a first portion arranged in the interior space of the distribution assembly, and the tube having a second portion arranged outside the distribution assembly.

4. The evaporation source of claim 1, the tube being partially arranged in a space between the distribution assembly and a heater of the distribution assembly.

5. The evaporation source of claim 1, the measurement assembly further comprising a heating arrangement at least partially arranged around the tube.

6. The evaporation source of claim 1, wherein the pressure sensor is a pressure sensor selected from the group consisting: a mechanical pressure sensor, a capacitive pressure sensor, and a thermal conductivity/convection vacuum gauges (pirani type).

7. The evaporation source of claim 2, wherein the purge gas introduction device includes a mass flow controller connected to an inert gas source.

8. The evaporation source of claim 2, wherein the purge gas introduction device is configured for providing a purge gas flow Q′ of 0.1 sccm≤Q′≤1.0 sccm.

9. The evaporation source of claim 1, wherein the tube has a diameter D of 1.0 mm≤D≤7.5 mm.

10. An evaporation source for deposition of a plurality of evaporated materials on a substrate, comprising:
a first crucible for evaporation of a first material;
a first distribution assembly with one or more outlets for providing the first evaporated material to the substrate, the first distribution assembly being in fluid communication with the first crucible;
a second crucible for evaporation of a second material;
a second distribution assembly with one or more outlets for providing the second evaporated material to the substrate, the second distribution assembly being in fluid communication with the second crucible; and
a measurement assembly comprising a tube arrangement and a purge gas introduction arrangement,
the tube arrangement having a first tube and a second tube, the first tube connecting a first interior space of the first distribution assembly with a pressure sensor, the second tube connecting a second interior space of the second distribution assembly with the pressure sensor, and
the purge gas introduction arrangement having a first purge gas introduction device connected to the first tube and a second purge gas introduction device connected to the second tube.

11. An evaporation source for deposition of evaporated material on a substrate, comprising:
a crucible for material evaporation;
a distribution assembly with one or more outlets for providing the evaporated material to the substrate, the distribution assembly being in fluid communication with the crucible; and
a measurement assembly comprising a tube connecting an interior space of the crucible with a pressure sensor.

12. A deposition apparatus for applying material to a substrate, comprising:
a vacuum chamber;
an evaporation source provided in the vacuum chamber, the evaporation source having a crucible, and a distribution assembly; and
a measurement assembly for measuring a vapor pressure in the distribution assembly, the measurement assembly comprising a tube having a first end and a second end, the first end is arranged in an interior space of the distribution assembly, and the second end is connected to a pressure sensor.

13. A method of measuring a vapor pressure in an evaporation source having a crucible and a distribution assembly, the method comprising:
providing a measurement assembly comprising a tube having a first end and a second end;
arranging the first end in an interior space of the distribution assembly;
connecting the second end to a pressure sensor;
evaporating a material for providing the evaporated material;
guiding the evaporated material from the crucible into the distribution assembly; and
measuring a pressure provided at the second end of the tube using the pressure sensor.

14. The method of claim 13, further comprising heating at least a portion of the tube.

15. The method of claim 13, further comprising introducing a purge gas into the tube.

16. A method for determining an evaporation rate of an evaporated material in an evaporation source, comprising:
measuring a vapor pressure of the evaporated material in the evaporation source; and
calculating the evaporation rate from the measured vapor pressure.

17. A method of measuring a vapor pressure difference in an evaporation source having a crucible and a distribution assembly, the method comprising:
providing a first measurement assembly comprising a tube connecting an interior space of the distribution assembly with a first pressure sensor, the tube having a tube opening provided at a first position in the interior space of the distribution assembly;
providing a second measurement assembly comprising a further tube connecting an interior space of the evaporation source with a second pressure sensor, the further tube having a further tube opening provided at a second position in the interior space of the distribution assembly or in an interior space of the crucible;
measuring the vapor pressure difference in the evaporation source using the first pressure sensor and the second pressure sensor.

18. The deposition apparatus of claim 12, the measurement assembly further comprising a purge gas introduction device connected to the tube.

19. The method of claim 13, further comprising introducing a purge gas into an end portion of the tube being connected to the pressure sensor.

20. The method of claim 16, wherein measuring the vapor pressure of the evaporated material in the evaporation source comprises:
providing a measurement assembly comprising a tube having a first end and a second end;
arranging the first end in an interior space of a distribution assembly of the evaporation source;
connecting the second end to a pressure sensor;
evaporating a material for providing the evaporated material;
guiding the evaporated material from a crucible of the evaporation source into the distribution assembly; and
measuring a pressure provided at the second end of the tube using the pressure sensor.
